(19) United States
(12) Patent Application Publication
(10) Pub. No.: US 2019/0253020 A1
(43) Pub. Date: Aug. 15, 2019

(54) SOLAR TRACKER AND SOLAR ENERGY COLLECTION SYSTEM

(71) Applicant: SHANGHAI IC R&D CENTER CO., LTD., Shanghai (CN)

(72) Inventors: Jiayin Chen, Shanghai (CN); Jianxin Wen, Shanghai (CN); Chen Li, Shanghai (CN)

(21) Appl. No.: 16/128,501

(22) Filed: Sep. 11, 2018

Related U.S. Application Data
(63) Continuation-in-part of application No. 15/100,341, filed on May 31, 2016, now abandoned.

(30) Foreign Application Priority Data
Jan. 29, 2014 (CN) 201410043672.0
Apr. 10, 2014 (CN) 201410142600.1

(51) Int. Cl. H02S 20/32; H01L 27/146; G01S 3/786; G05D 3/10

(52) U.S. Cl. CPC H02S 20/32; G05D 3/105; G01S 3/7861; H01L 27/14627

(57) ABSTRACT

The present invention provides a solar tracker comprising a supporting unit holding a solar panel, a driving unit regulating the position of the supporting unit, an image sensor having incident angle sensitivity characteristic, an identification unit identifying the current incident angle of the sunlight according to the signal output by the image sensor, and a control unit controlling the driving unit to regulate the position of the supporting unit according to the current incident angle to make the sunlight vertically incident upon the solar panel. The micro lens of each pixel in the image sensor only refracts incident light with a certain specific angle to vertically incident upon the photodiode below the micro lens.

### CROSS-REFERENCE TO RELATED APPLICATION

This application is Continuation-In-Part of U.S. patent application Ser. No. 15/100,341, filed on May 31, 2016, which claims the priority benefit of International Patent Application Serial No. PCT/CN2014/094,631, filed Dec. 23, 2014, which is related to and claims the priority benefit of China patent application serial No. 201410142600.1 filed Apr. 10, 2014, which claims the priority benefit of China patent application serial No. 201410043672.0 filed Jan. 29, 2014. The entirety of each of the above-mentioned patent applications is hereby incorporated by reference herein and made a part of this specification.

### FIELD OF THE INVENTION

The present invention generally relates to the field of solar power application, and more particularly to a solar tracker sensitive to sunlight incident angle and a solar energy collection system having the solar tracker.

### BACKGROUND OF THE INVENTION

The energy problem is a great issue worldwide since it is critical to the development and future of the human society. For a long period, non-renewable fossil energy such as coal and oil has been the main energy source used in the industry field or the civilian field. Particularly, coal is used as the conventional energy source to generate electricity energy. However, according to incomplete statistics, the fossil energy will face complete exhaustion in the coming fifty years due to excessive exploitation and over-use.

Therefore, renewable energy such as wind energy and tidal energy which can take the place of the fossil energy aforementioned is gaining more and more attention. Particularly, the solar power generation is one of the critical indispensable techniques for the human sustainable development.

Compared with the fossil energy, the renewable energy has the advantages of sustainable use and environmental protection. However, the renewable energy mainly depends on the natural environment. For example, the wind energy completely relies on the wind rate and wind direction, the solar energy relies on the intensity and the incident angle of the sunlight. Furthermore, constrained by the conventional technology, the exploration of the renewable energy is facing the deficiencies of low efficiency and high expenditure. Therefore, how to make use of the science technology progress for the energy industry to greatly improve the utilization efficiency of the renewable energy is a significantly meaningful project.

Concerning the solar energy, sunlight is collected and converted to electricity by a solar panel, which is a key component for the solar power generation, during the solar power generation.

In the prior art, the solar panel is categorized as either fixed or movable according to whether it changes its position during use. The fixed solar panel is installed at a fixed orientation facing towards the sky according to the longitude and latitude information of its location, and makes no position change during use; while the movable solar panel keeps changing its orientation to receive vertical incidence of the sunlight. Since the movable solar panel can continuously change its orientation and adjust its position to achieve relative high utilization efficiency, it becomes more and more popular.

Solar following device with a movable solar panel can be divided into two broad categories: heliostat and solar tracker. The former usually supports a plane mirror surface with optical path towards the solar panel or solar heater; the latter supports the solar panel with optical path towards the normal line direction of the solar panel.

The solar tracker can be further divided into two types: single-axis type and dual-axis type. FIG. 1 is a structural view of the conventional single-axis solar tracker. As shown in FIG. 1, the conventional single-axis type solar tracker comprises a cylindrical supporting arm 701 installed with a solar panel 702 at its upper end through a rotating shaft 703. During the installation, the axis of the rotating shaft 703 should be kept parallel to the longitude lines of the earth. As shown in FIG. 2, which is an operational view of the single-axis solar tracker, the normal line direction of the solar panel 702 is changed by adjusting the rotation angle “a” of the rotating shaft 703. Therefore, the single-axis solar tracker only has one degree of freedom to rotate around one rotation axis. The dual-axis solar tracker has two degrees of freedom to rotate around two rotation axis. As shown in FIG. 3 and FIG. 4, in the conventional dual-axis solar tracker, the cylindrical supporting arm 1201 is installed with a solar panel 1202 at its upper end through two rotating shafts 1203. The normal line direction of the solar panel surface is determined by the rotation angles “a” and “b”. During the installation, the axis of one rotating shaft 1203 is kept parallel to the longitude lines and the axis of the other rotating shaft 1203 is kept parallel to the latitude lines of the earth. The single-axis solar tracker is widely adopted due to its simple implementation and low installation cost, while the dual-axis solar tracker is rarely used due to its complex implementation and high installation cost.

FIG. 5 is a view showing the relationship between the direct sunlight and the tropic of Cancer.

The relative movement between the sun and a given position on the earth can be considered as a synthetic motion of the earth's rotation and the earth's revolution. The earth's rotation contributes to the solar movement relative to the given position in one day and the earth's revolution contributes to the change of the daily solar movement relative to the given position in a year. The sunlight shoots directly on the north hemisphere at a maximum northern latitude of 23° 26′. Correspondingly, the sunlight shoots directly on the south hemisphere at a maximum south latitude of 23° 26′ (not shown). Therefore, the dual-axis solar tracker is preferred to be positioned at low latitudes between the tropic of Cancer and the tropic of Capricorn to follow the sun's path during the earth's revolution by using the second rotational degree of freedom. In general, the rotating shaft of the single-axis solar tracker or the first rotating shaft of the dual-axis solar tracker should be positioned along the longitude lines of the earth so that it can be rotated to track the motion of the sunlight caused by the earth's rotation.

However, no matter what kind of solar tracker aforementioned is used, during the installation, the latitude and longitude information of the installation place should be considered to regulate the solar tracker to track the direct sunlight and to maximize the photoelectric transformation performed by the solar panel, which makes the technique application complex and expensive.

### BRIEF SUMMARY OF THE DISCLOSURE

The main objective of the present invention is to provide a solar tracker sensitive to sunlight incident angle and a solar energy collection system having the solar tracker, so as to solve the problems of complex installation and high cost due to the limitation of considering the latitude and longitude information of the installation place.

To achieve the above objective, the present invention provides a solar tracker comprising: a supporting unit, a driving unit for regulating a position of the supporting unit, an image sensor having incident angle sensitivity characteristic, an identification unit and a control unit. The supporting unit has a supporting plate for holding a solar panel. The image sensor includes multiple pixels each comprising a photodiode and a micro lens above the photodiode, wherein the micro lens is made of gradient refractive index material only sensitive to incident light with a certain specific incident angle to make such incident light vertically incident upon the photodiode therebelow, the photodiode performs photoelectric transformation to the received vertical incident light and outputs an electric signal; wherein the gradient refractive index materials of the micro lenses are different from each other such that the specific incident angles of the incident lights refracted by the micro lenses of the image sensor are different and are one-to-one correspondent to various incident angles of the sunlight incident upon the image sensor. The identification unit identifies a current incident angle of the sunlight incident upon the image sensor according to all the electric signals output by all the photodiodes; wherein the current incident angle of the sunlight incident upon the image sensor is the specific angle of the incident lights refracted by the micro lens below which the photodiode outputs the strongest electric signal among the electric signals output by all the photodiodes. The control unit controls the driving unit to regulate the position of the supporting unit according to the current incident angle to make the sunlight vertically incident upon the solar panel.

Preferably, the specific angle is an angle between the incident light and the normal line of the plane of the photodiode.

Preferably, the solar tracker is a single-axis solar tracker, the driving unit is a rotating shaft connected to the supporting unit and positioned parallel to a central line of the supporting plate and the longitude lines of the earth; the control unit regulates the rotation angle of the rotating shaft according to the current incident angle of the sunlight to make the sunlight vertically incident upon the solar panel.

Preferably, the multiple photodiodes of the image sensor form at least one pixel sub-array; for the micro lenses in the same row of the pixel sub-array, the corresponding specific angles change from a maximum negative angle to a maximum positive angle.

Preferably, the specific angle comprises a first angle component and a second angle component, wherein the first angle component is an angle between the incident light and the normal line of the plane of the photodiode, the second angle component is an angle between a projection of the incident light in a plane of the photodiode and an axis in the same plane.

Preferably, the solar tracker is a dual-axis solar tracker, the driving unit comprises a first rotating shaft connected to the supporting unit and positioned parallel to the supporting plate and a second rotating shaft connected to the supporting unit and positioned vertical to the supporting plate; the first rotating shaft is parallel to the longitude lines of the earth and the second rotating shafts is parallel to the latitude lines of the earth; the control unit regulates rotation angles of the first rotating shaft and the second rotating shaft to make the sunlight vertically incident upon the solar panel according to the first angle component and the second angle component of the current incident angle of the sunlight.

Preferably, the multiple photodiodes of the image sensor form at least one pixel sub-array, the multiple micro lenses are sensitive to the specific angles whose first angle components change from a maximum negative angle to a maximum positive angle in the same row of the pixel sub-array while keep same in the same column of the pixel sub-array and whose second angle components change from 0° to 360° in the pixel sub-array.

Preferably, the image sensor is positioned on the supporting plate where unoccupied by the solar panel.

The present invention also provides a solar energy collection system having a solar panel which absorbs the sunlight and transforms to electricity and the solar tracker mentioned above.

Compared with the prior art, the present invention utilizes the image sensor having micro lens each sensitive to a certain specific angle to identify a micro lens which refracts the incident sunlight to vertical incident upon the photodiode below it from the signals output by all the photodiodes, so as to identify the specific angle as the current incident angle of the sunlight to the plane of the image sensor. Furthermore, the control unit controls the driving unit to regulate the position of the solar panel according to the current incident angle of the sunlight to make the sunlight vertically incident upon the solar panel so as to realize the sunlight track. Therefore, the solar tracker of the present invention can be installed without considering the latitude and longitude information of the installation place, which simplifies the application and reduces the cost.

### BRIEF DESCRIPTION OF THE DRAWINGS

FIG. 1 and FIG. 2 are structural diagrams of the conventional single-axis solar tracker;

FIGS. 3-5 are structural diagrams of the conventional dual-axis solar tracker;

FIG. 6 is a diagram illustrating the relationship between the direct sunlight and the tropic of Cancer.;

FIG. 7 is a block diagram of the solar tracker in an embodiment of the present invention;

FIG. 8 and FIG. 9 are diagrams illustrating the refraction through the GRIN micro lens of the solar tracker in an embodiment of the present invention;

FIG. 10 is a front view of the single-axis solar tracker in an embodiment of the present invention;

FIG. 11 is a top view of the single-axis solar tracker in an embodiment of the present invention;

FIG. 12 is a motion diagram of the single-axis solar tracker in an embodiment of the present invention;

FIG. 13 is a view illustrating the pixel sub-array of the image sensor of the single-axis solar tracker in an embodiment of the present invention;

FIG. 14 is a section view illustrating the pixels of the module L in the pixel sub-array of the image sensor shown in FIG. 13;

FIG. 15 is a section view illustrating the pixels of the module R in the pixel sub-array of the image sensor shown in FIG. 13;

FIG. 16 is a plane view illustrating the pixels of the module L in the pixel sub-array of the image sensor shown in FIG. 13;

FIG. 17 is a plane view illustrating the pixels of the module R in the pixel sub-array of the image sensor shown in FIG. 13;

FIG. 18 is a front view of the dual-axis solar tracker in an embodiment of the present invention;

FIG. 19 is a top view of the dual-axis solar tracker in an embodiment of the present invention;

FIG. 20 and FIG. 21 are motion diagrams of the dual-axis solar tracker in an embodiment of the present invention;

FIG. 22 is a plane view illustrating the pixel module A of the image sensor of the dual-axis solar tracker in an embodiment of the present invention;

FIG. 23 is a plane view illustrating the pixel module B of the image sensor of the dual-axis solar tracker in an embodiment of the present invention;

FIG. 24 is a plane view illustrating the pixel module C of the image sensor of the dual-axis solar tracker in an embodiment of the present invention;

FIG. 25 is a plane view illustrating the pixel module D of the image sensor of the dual-axis solar tracker in an embodiment of the present invention;

FIG. 26 is a view illustrating the pixel array of the image sensor of the solar tracker in an embodiment of the present invention.

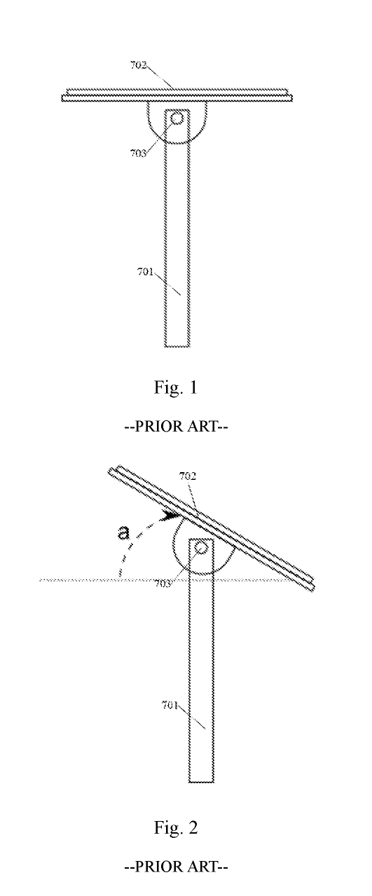

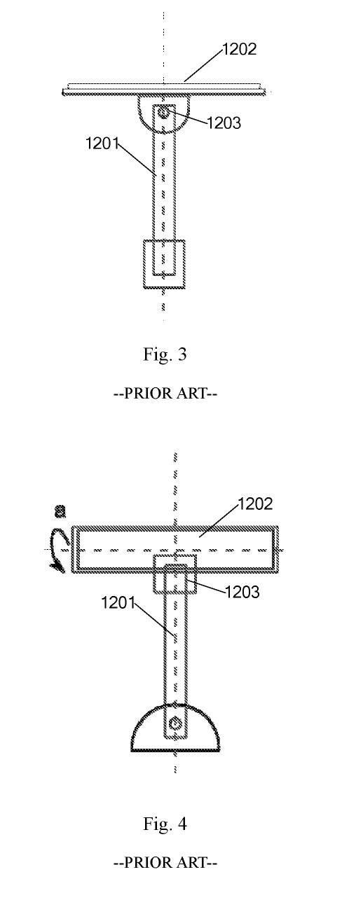

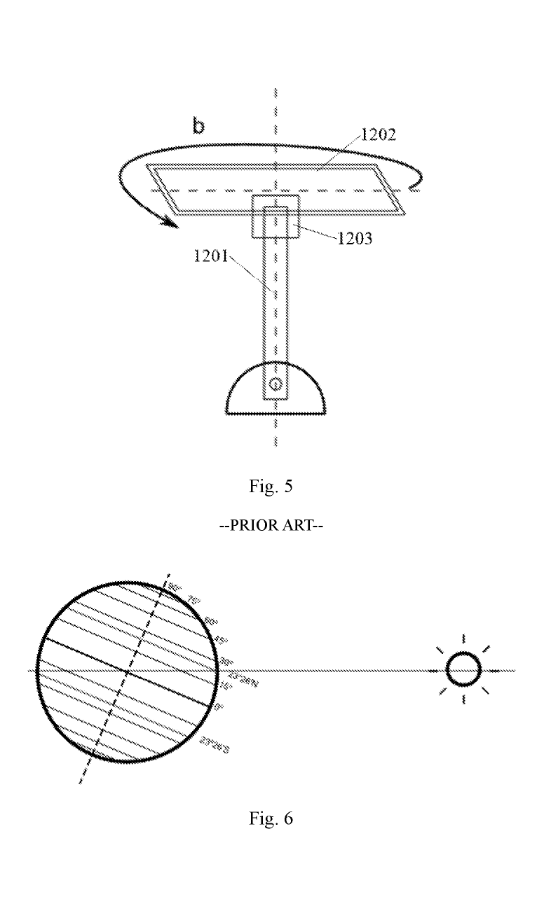

### DETAILED DESCRIPTION OF THE EMBODIMENTS

To understand the present invention more clearly and easily, the present invention will now be descried more fully hereinafter with reference to the accompanying drawings. The present invention shall not be limited to the embodiments set forth herein. General substitution known by the technical personnel in the art is within the protection scope of the present invention.

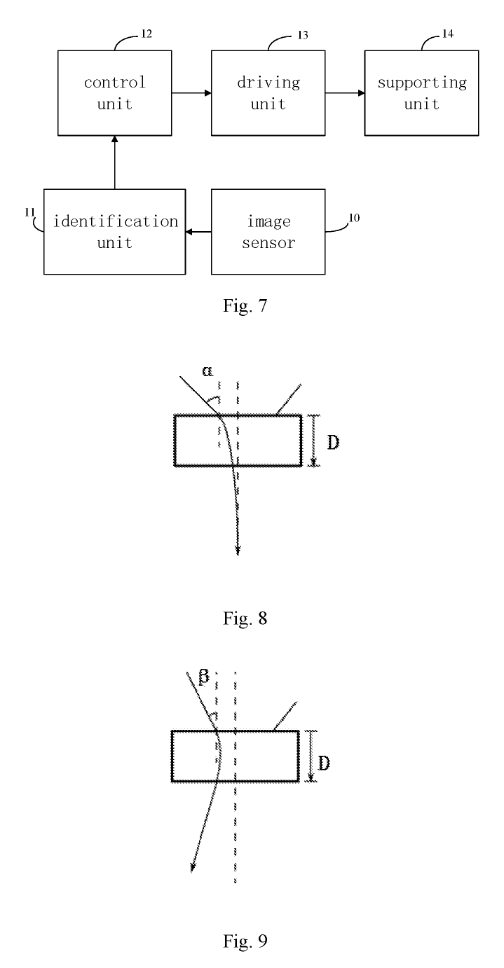

FIG. 7 is a block diagram of the solar tracker of the present invention. As shown in FIG. 7, the solar tracker comprises a supporting unit 14, a driving unit 13, a control unit 12, an identification unit 11 and an image sensor 10 having incident angle sensitivity characteristic. The supporting unit 14 has a supporting plate to hold a solar panel. The driving unit 13 regulates the position of the supporting unit 14, and also regulates the position of the solar panel. The identification unit 11 identifies the incident angle of the sunlight incident upon the image sensor 10 according to the signal output by the image sensor 10, and the control unit 12 constantly controls the driving unit 13 to regulate the position of the supporting unit 14 according to the current identified incident angle of the sunlight, so as to make the sunlight always incident vertically upon the solar panel, thereby tracking the sun's motion. Specifically, the image sensor 10 has multiple pixels each comprising a micro lens made of gradient refractive index (GRIN) material and a photodiode below the micro lens. The gradient refractive index materials of the micro lenses are different from each other. Accordingly, each micro lens is sensitive to only one unique specific angle. In other words, each micro lens only refracts incident light with a certain specific angle to vertically incident upon the photodiode below it. Each photodiode performs photoelectric transformation to the received vertical incident light and outputs corresponding electrical signal. Since the gradient refractive index materials of the micro lenses are different from each other, the specific angles sensitive by these micro lenses are different and are one-to-one correspondent to various possible incident angles of the sunlight incident upon the image sensor. FIG. 8 and FIG. 9 are schematic diagrams illustrating the refraction of the light through the GRIN micro lens of the solar tracker in which the dotted line refers to the normal line of the plane of the photodiode. FIG. 8 illustrates the refraction of the light with an incident angle of a through the GRIN micro lens with a thickness of D. The refracted light orientates parallel to the normal line, that is, the refracted light incidents vertically upon the photodiode. FIG. 9 illustrates the refraction of the light with an incident angle of β through the same GRIN micro lens. The refracted light is emitted at an angle unparallel to the normal line. According to the schematic diagrams above, the GRIN micro lens is only sensitive to one specific angle. In other words, if the GRIN micro lens is sensitive to the specific angle α, then it only bends the light whose incident angle is a to be parallel to the normal line of the photodiode surface to vertically incident upon the photodiode. When the light incidents to the micro lens at other incident angles, the light refracted by the micro lens cannot vertically incident upon the photodiode below, thus the photodiode can only absorb very little light. Since the image sensor 13 has multiple pixels, and different pixels comprise micro lens sensitive to different specific angles, the image sensor can capture sunlight of various incident angles in general. The photodiode transforms the photons from the received sunlight into electrons and generates the electrical signal. When the incident angle of the sunlight to the plane of the image sensor is a, the photodiode below the micro lens sensitive to the specific angle of a generates the strongest electrical signal after photoelectric transformation. The identification unit 11 receives the electrical signal from all the photodiodes and identifies the specific angle sensitive by the micro lens below which the photodiode outputs the strongest electric signal as the current incident angle of the sunlight incident upon the image sensor. The control unit 12 is connected with the identification unit 11 and the driving unit 13, it controls the driving unit 13 to regulate the position of the supporting unit 14 according to the current incident angle of the sunlight identified by the identification unit 11, so as to make the sunlight vertically incident upon the solar panel on the supporting unit 14. Since the identification unit 11 can real-time detect the current sunlight incident angle and the control unit 12 can adjust the position of the supporting unit 14 accordingly, the tracking of the sunlight can be realized by the solar tracker of the present invention. Furthermore, the solar panel hold by the solar tracker which absorbs the sunlight and transforms it into electricity can be combined with the solar tracker to form a solar energy collection system which maximize the utilization of the solar energy.

As mentioned above, the conventional solar tracker can be categorized as either single-axis type or dual-axis type. The solar tracker of the present invention can also be a single-axis or dual axis solar tracker.

### First Embodiment

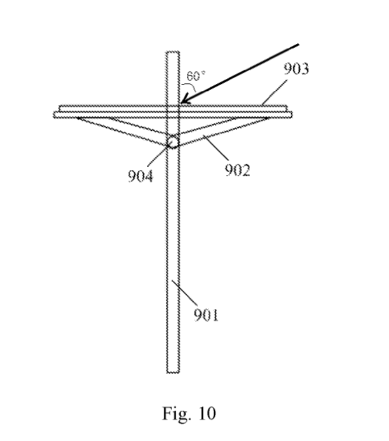

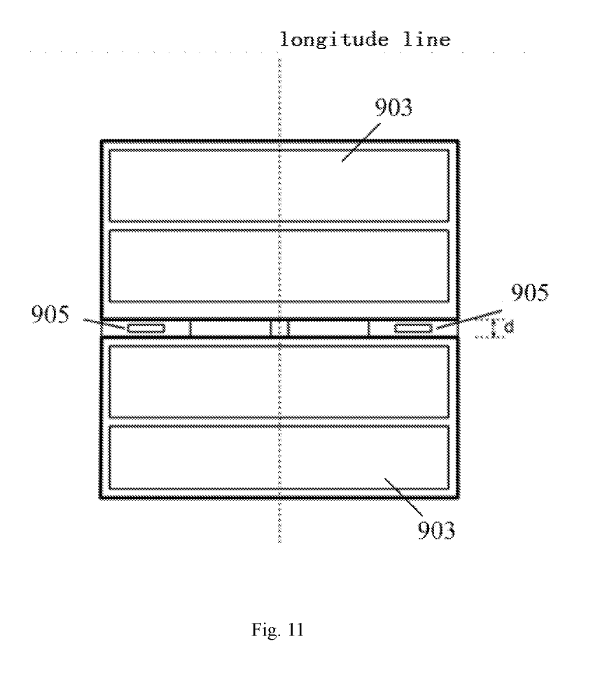

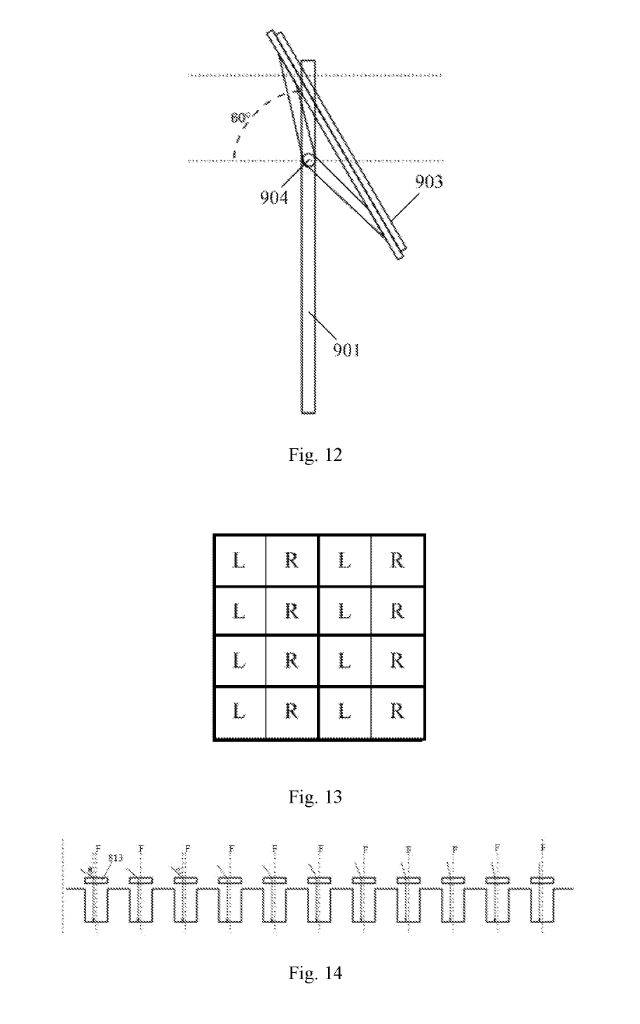

A single-axis solar tracker in the embodiment of the present invention will be described with reference to FIGS. 10˜17. Referring to FIGS. 10˜12, the supporting unit of the single-axis solar tracker comprises a supporting arm 901, a supporting bracket 902 mounted on the supporting arm 901, and a supporting plate mounted on the supporting bracket. The supporting plate holds the solar panel 903. In the embodiment, the driving unit is a rotating shaft 904 connected to the supporting unit. Specifically, the rotating shaft 904 is connected to the bottom of the supporting bracket 902 and is positioned parallel to the central line of the supporting plate. When the rotating shaft 904 is rotated, it drives the supporting plate and the solar panel to be rotated, thus to change the position of the solar panel. Therefore, by the control unit adjusting the rotation angle of the rotating shaft 904 according to the current sunlight incident angle, the sunlight can incident vertically upon the solar panel. As shown in FIG. 11, the image sensor 905 is mounted on the supporting plate where unoccupied by the solar panel 903. Since the image sensor 905 is substantially coplanar with the solar panel 903, the incident angle of the sunlight relative to the image sensor 905 equals to the incident angle of the sunlight relative to the solar panel, and the control unit can easily calculate the rotation angle need to be adjusted for the solar panel. In the embodiment, two image sensors 905 are provided on both sides of the central line of the supporting plate, the connecting line between the two image sensors 905 is vertical to the longitude lines. To ensure a free rotation of the supporting plate with the rotating shaft 904, the supporting plate has a hollowed-out structure at each side of the central line to place one image sensor 905. The width “d” of the hollowed-out structure affects the surface area of the solar panel and it should be minimized to increase the photoelectric transformation efficiency of the solar panel. Furthermore, since the single-axis solar tracker has only one rotating shaft 904, the rotating shaft 904 should be mounted to be parallel to the longitude lines of the earth so as to improve the power generation efficiency of the solar tracker. FIG. 12 is a motion diagram of the single-axis solar tracker. When the incident angle of the sunlight relative to the image sensor is 60° (as shown in FIG. 10), the control unit controls the rotating shaft 904 to rotate 60° clockwise, which makes the sunlight vertically incident upon the solar panel 903 to maximize the photoelectric transformation.

It is noted that for the single-axis solar tracker, the specific angle sensitive by the image sensor is a one-dimensional angle which is represented by an angle between the incident light and the normal line (axis z) of the plane of the photodiode.

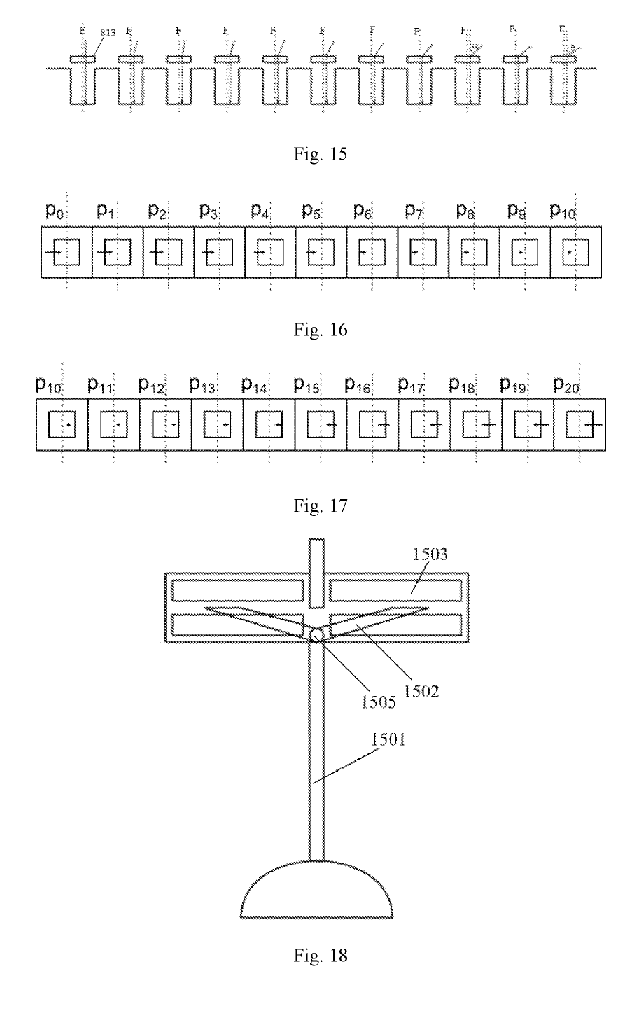

FIG. 13 illustrates the pixel sub-array of the image sensor of the single-axis solar tracker. As shown in FIG. 13, the multiple pixels of the image sensors form multiple pixel sub-arrays, each pixel sub-array comprises a pixel module L and a pixel module R. All the pixel modules of the image sensor are arranged in the order of LRLRLR . . . in the row direction and are arranged to be the same type (pixel module L or pixel module R) in the column direction, thus the pixel modules form a large pixel array. In the embodiment, each pixel module L or pixel module R comprises pixels arranged in a matrix of one row and multiple columns, while in other embodiments, the pixel module can also be composed of pixels arranged in multiple rows and multiple columns. FIG. 14 is a section view of the pixels in the pixel module L and FIG. 15 is a section view of the pixels in the pixel module R For illustrative purpose, structures such as the substrate, the photodiodes and the metal layers are omitted, only the micro lenses 813 are illustrated. The micro lenses 813 are only sensitive to the variation of the one-dimensional angle between the incident light and the normal line of the plane of the photodiode. As shown in FIG. 14, the specific angle sensitive by the micro lens of each pixel in the pixel module L is the angle between the light incident from the top left and the normal line F of the plane of the photodiode. By using different gradient refractive index materials for all the micro lenses, the specific angles sensitive by the micro lenses change gradually from −θ to 0°. Each micro lens only refracts the incident light with the sensitive specific angle to make it vertically incident to the photodiode surface. As shown in FIG. 15, the specific angle sensitive by the micro lens of each pixel in the pixel module R is the angle between the light incident from the top right and the normal line F of the plane of the photodiode. By using different gradient refractive index materials for the micro lenses, the specific angles sensitive by the micro lenses change gradually from 0° to θ. Each micro lens only refracts the incident light with the sensitive specific angle to make it vertically incident to the photodiode surface. Since the specific angle θ refers to the angle between the sunlight and the normal line of the photodiode plane, it ranges from 0° to 90°. For each pixel, the specific angle sensitive by the micro lens has a one-to-one mapping relationship with the index address of the pixel, which meets the following function: specific angle θ=f(index Pixel). As shown in FIG. 16, for the pixel module L, the maximum specific angle −θ corresponds to the pixel p0, the minimum specific angle θ corresponds to the pixel p10. Pixels p0, p1, p2, p10 are arranged in order from left to right. As shown in FIG. 17, for the pixel module R, the minimum specific angle θ corresponds to the pixel p10, the maximum specific angle θ corresponds to the pixel p20. Pixels p10, p11, p12, p20 are arranged in order from left to right. Accordingly, the pixel sub-array composed of one pixel module L and one pixel module R has pixels arranged in one row and 21 columns in which the pixel 10 is shared by the pixel module L and the pixel module R. Therefore, in the pixel sub-array, the micro lenses of the pixels in one row are sensitive to the specific angles changing from the maximum negative angle −θ to the maximum positive angle θ gradually. Furthermore, if the pixel module L or pixel module R comprises pixels arranged in multiple rows and multiple columns, the micro lenses in the same column of the pixel module are sensitive to the same specific angle. If the index address of each pixel is represented by a binary code, then the specific angle corresponding to the pixel can be obtained according to the binary code. Moreover, the resolution of the image sensor is determined by the number of the pixel sub-arrays. Accordingly, the more pixel sub-arrays are provided in the image sensor, the more specific angles can be identified. In the embodiment, the specific angle sensitive by the micro lens is an one-dimensional angle as it refers to the angle between the incident light and the normal line of the photodiode plane, the single-axis solar tracker follows the sun's motion via the plurality of the one-dimensional angles.

### Second Embodiment

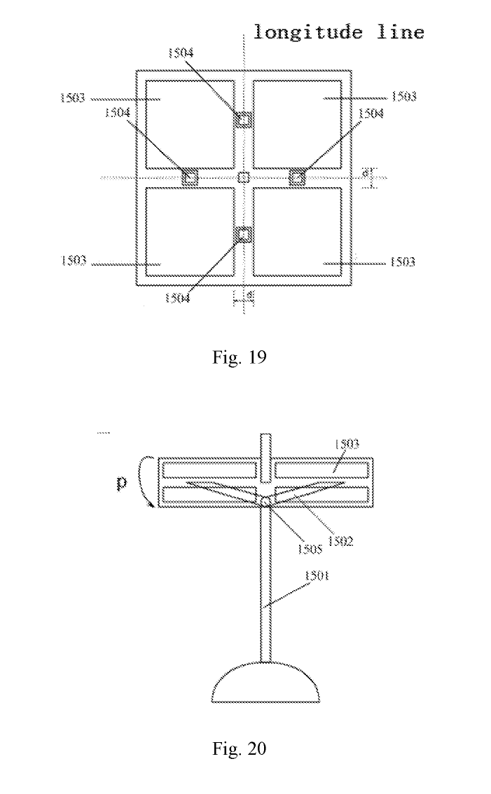

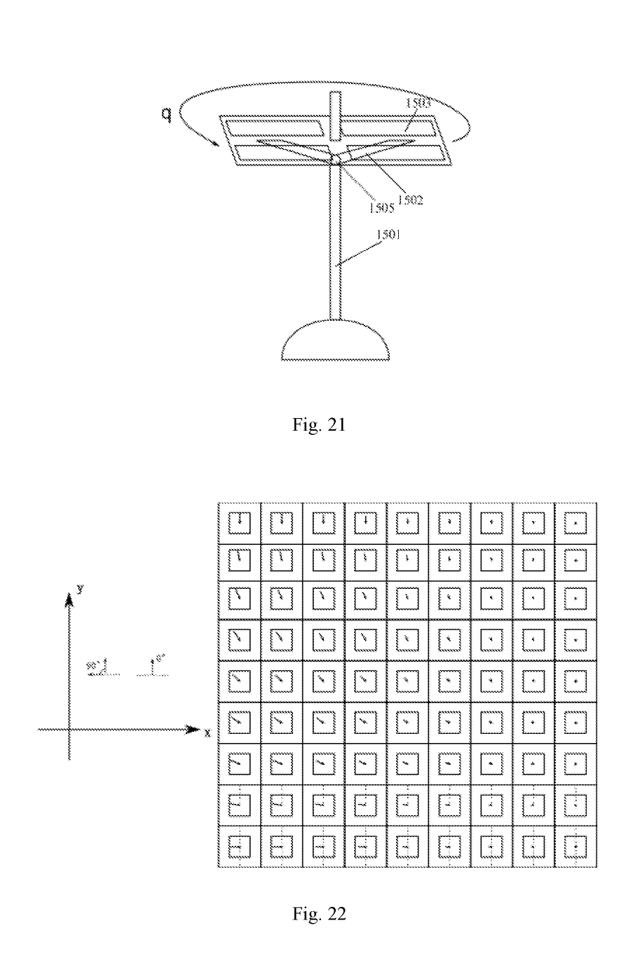

The dual-axis solar tracker in the embodiment of the present invention will be described with reference to FIGS. 18˜26. As shown in FIGS. 18˜21, the supporting unit of the dual-axis solar tracker comprises a supporting arm 1501, a supporting bracket 1502 mounted on the supporting arm 1501, and a supporting plate mounted on the supporting bracket 1502. The supporting plate holds four solar panels 1503. In the embodiment, the driving unit comprises a first rotating shaft 1505 and a second rotating shaft which are both connected to the supporting unit. Specifically, the first rotating shaft 1505 is connected to the bottom of the supporting bracket 1502 and is positioned parallel to the central line of the supporting plate. The second rotating shaft is coaxially positioned inside the supporting arm 1501 extending through the center of the supporting plate to be vertically connected to the supporting plate. The first rotating shaft 1505 is parallel to the longitude lines of the earth and the second rotating shaft is parallel to the latitude lines of the earth. With the rotation of the two rotating shafts, the supporting plate and the solar panel 1501 are also rotated to change their position. Therefore, by the control unit adjusting the rotation angle of the two rotating shafts according to the current sunlight incident angle, the sunlight can incident vertically upon the solar panel. As shown in FIG. 19, four image sensors 1504 are mounted on the supporting plate where unoccupied by solar panels 903. Since the image sensors 1504 are substantially coplanar with the solar panels 1503, the incident angle of the sunlight relative to the image sensors equals to the incident angle of the sunlight relative to the solar panels, and the control unit can easily calculate the rotation angle need to be adjusted for the solar panels. In the embodiment, the four image sensors are arranged symmetrically, each positioned between two adjacent solar panels. Specifically, the supporting plate has hollowed-out structures each having a width of “d” around the center of the supporting plate for placing the image sensors. As shown in FIG. 20 and FIG. 21, the control unit controls the first rotating shaft 1505 to rotate an angle of p and controls the second rotating shaft to rotate an angle of q, so as to make the solar panels 1503 face towards the sunlight.

For the dual-axis solar tracker, the actual incident angle of the sunlight in three dimensional space cannot be determined by using only one-dimensional angle information, thus the specific angle sensitive by the image sensor comprises an angle between the incident light and the normal line (axis z) of the plane of the photodiode, as well as an angle between the projection of the incident light in the plane of the photodiode and an axis (axis x or y) in the same plane. Accordingly, in the embodiment, the angle between the incident light and the normal line (axis z) of the photodiode plane forms a first angle component of the specific angle, and the projected angle of the sunlight in the photodiode plane (the angle between the projection of the sunlight in the plane of the photodiode and the axis x or y in the same plane) forms a second angle component of the specific angle. As shown in FIGS. 22˜25 which illustrate the pixel array of the image sensor, each first angle component is represented by a plane vector, the arrow of the plane vector represents the positive or negative characteristic of the vector value. If the arrow of the plane vector of the first angle component is headed towards right, then the value of the first angle component is negative, otherwise the value of the first angle component is positive. The length of the plane vector represents the degree of the first angle component, the greater the vector length, the bigger the first angle component. The second angle component is represented by the orientation change of the plane vector in the photodiode plane. In the embodiment, the degree of the first angle component changes from 0° to θ. Since the first angle component is the angle between the sunlight and the normal line of the photodiode plane, degree θ should ranges from 0° to 90°. The second angle component changes from 0° to 360°.

As shown in FIGS. 22˜25, the multiple pixels of the image sensors are divided into four groups according to the angular range of the first and second angle components. Wherein, the second angle component is the angle between the projection of the sunlight in the photodiode plane and the axis y of the photodiode plane.

(1) pixel module A: as shown in FIG. 22, the micro lenses in the pixel module A are sensitive to the sunlight incident from top left. Specifically, the first angle component ranges from −θ˜0°, the second angle component ranges from 0°˜90°. The pixels in the same column of the pixel module A are sensitive to the specific angles having the same first angle components and the second angle components change from 0°˜90° gradually, while the pixels in the same row of the pixel module A are sensitive to the specific angles having the first angle components change from −θ˜0 gradually and the same second angle components.

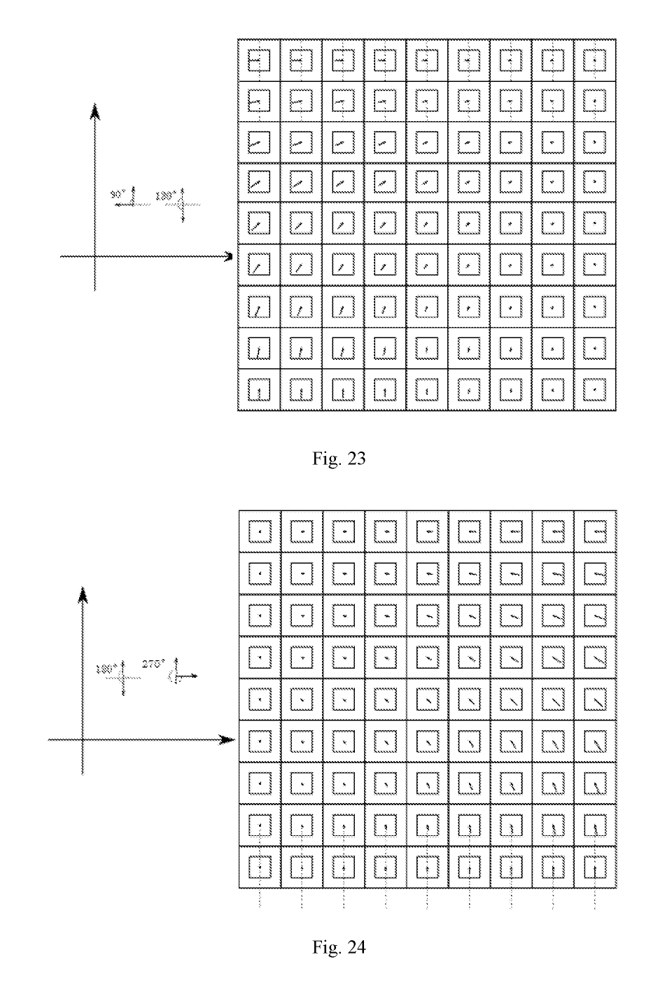

(2) pixel module B: as shown in FIG. 23, the micro lenses in the pixel module B are sensitive to the sunlight incident from top left. Specifically, the first angle component ranges from −θ˜0°, the second angle component ranges from 90°˜180°. The pixels in the same column of the pixel module B are sensitive to the specific angles having the same first angle components and the second angle components change from 90°˜180° gradually, while the pixels in the same row of the pixel module B are sensitive to the specific angles having the first angle components change from −θ˜0 gradually and the same second angle components.

(3) pixel module C: as shown in FIG. 24, the micro lenses in the pixel module C are sensitive to the sunlight incident from top right. Specifically, the first angle component ranges from 0°˜θ, the second angle component ranges from 180°˜270°. The pixels in the same column of the pixel module C are sensitive to the specific angles having the same first angle components and the second angle components change from 180°˜270° gradually, while the pixels in the same row of the pixel module C are sensitive to the specific angles having the first angle components change from 0°˜θ gradually and the same second angle components.

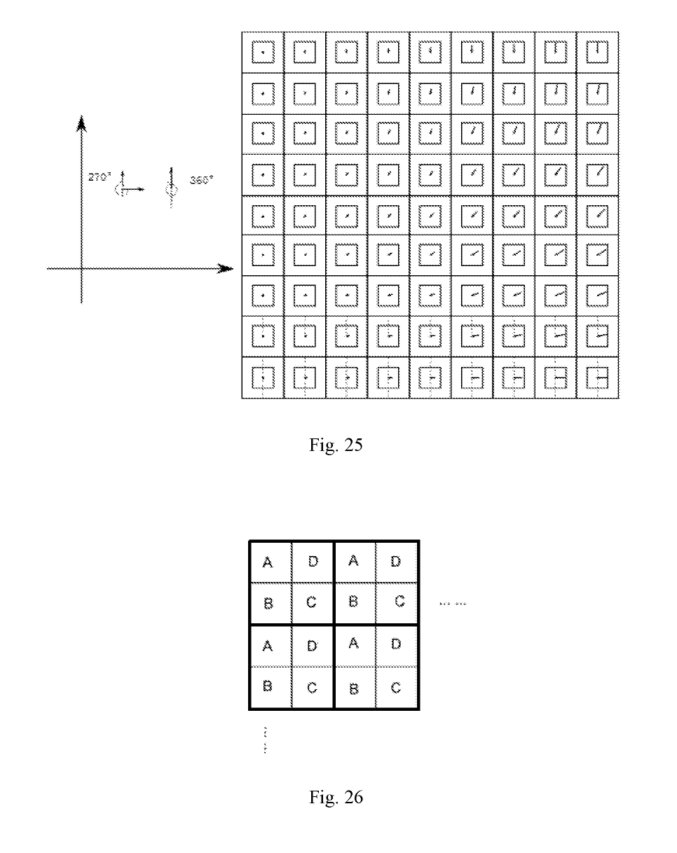

(4) pixel module D: as shown in FIG. 25, the micro lenses in the pixel module D are sensitive to the sunlight incident from top right. Specifically, the first angle component ranges from 0°˜θ, the second angle component ranges from 270°˜360°. The pixels in the same column of the pixel module D are sensitive to the specific angles having the same first angle components and the second angle components change from 270°˜360° gradually, while the pixels in the same row of the pixel module D are sensitive to the specific angles having the first angle components change from 0°˜θ gradually and the same second angle components.

FIG. 26 illustrates a pixel array of the image sensor of the dual-axis solar tracker. The pixel array comprises a plurality of pixel sub-arrays. As shown in FIG. 26, each pixel sub-array is composed of pixel modules A˜D arranged counterclockwise. Therefore, in the same row of the pixel sub-array, the first angle components change from the negative maximum −θ to the positive maximum θ gradually, while in the same column, the first angle components are the same. In addition, in each pixel sub-array, the second angle components change gradually from 0°˜360°. Similar to the first embodiment, the identification unit identifies the specific angle sensitive by the micro lens of the pixel whose photodiode outputs the biggest electric signal among all the pixels according to the mapping relationship between the pixel index address and the specific angle of each pixel. In the embodiment, the specific angle comprises the first angle component and the second angle component, the identification unit obtains the first and second angle components according to the pixel index address, and the control unit controls the rotation of the first rotating shaft and the rotation of the second rotating shaft according to the first angle component and the second angle component, so as to adjust the variation of the rotation angle p and q respectively to make the sunlight vertically incident upon the solar panels.

In summary, the solar tracker of the present invention utilizes the image sensor having incident angle sensitivity characteristic, it can be mounted without considering the latitude and longitude information of the installation place, which simplifies the installation process. Furthermore, since the solar track can automatically regulate the direction of the supporting unit as well as the solar panel according to the motion of the sun, it can be mounted in various places, which improves the applicability.

Although the present invention has been disclosed as above with respect to the preferred embodiment, they should not be construed as limitations to the present invention. Various modifications and variations can be made by the ordinary skilled in the art without departing the spirit and scope of the present invention. Therefore, the protection scope of the present invention should be defined by the appended claims.

1. A solar tracker, comprising:
a supporting unit having a supporting plate for holding a solar panel;
a driving unit for regulating the position of the supporting unit;
an image sensor having incident angle sensitivity characteristic including multiple pixels, wherein each pixel comprises a photodiode, and a micro lens made of gradient refractive index material which only refracts incident light with a certain specific incident angle to make such incident light vertically incident upon the photodiode therebelow, the photodiode performs photoelectric transformation to the received vertical incident light and outputs the electric signal; wherein the gradient refractive index materials of the micro lenses are different from each other such that the specific incident angles of the incident lights refracted by the micro lenses of the image sensor are different and are one-to-one correspondent to the various incident angles of the sunlight incident upon the image sensor;
an identification unit identifying a current incident angle of the sunlight incident upon the image sensor according to all the electric signals output by all the photodiodes; wherein in the current incident angle of the sunlight incident upon the image sensor is the specific angle of the incident lights refracted by the micro lens below which the photodiode outputs the strongest electric signal among the electric signals output by all the photodiodes;
a control unit controlling the driving unit to regulate the position of the supporting unit to make the sunlight vertically incident upon the solar panel according to the current incident angle.

2. The image sensor according to claim 1, wherein the specific angle is the angle between the incident light and the normal line of the plane of the photodiode.

3. The image sensor according to claim 2, wherein the solar tracker is a single-axis solar tracker, the driving unit is a rotating shaft connected to the supporting unit and positioned parallel to the central line of the supporting plate and the longitude lines of the earth; the control unit regulates the rotation angle of the rotating shaft to make the sunlight vertically incident upon the solar panel according to the current incident angle of the sunlight.

4. The image sensor according to claim 3, wherein the multiple photodiodes of the image sensor form at least one pixel sub-array; for the micro lenses of the pixels in the same row of the pixel sub-array, the corresponding specific angles change from the maximum negative angle to the maximum positive angle.

5. The image sensor according to claim 1, wherein the specific angle comprises a first angle component and a second angle component, wherein the first angle component is the angle between the incident light and the normal line of the plane of the photodiode, the second angle component is the angle between the projection of the incident light in the plane of the photodiode and an axis in the same plane.

6. The image sensor according to claim 5, wherein the solar tracker is a dual-axis solar tracker, the driving unit comprises a first rotating shaft connected to the supporting unit and positioned parallel to the supporting plate and a second rotating shaft connected to the supporting unit and positioned vertical to the supporting plate; the first rotating shaft is parallel to the longitude lines of the earth and the second rotating shafts is parallel to the latitude lines of the earth; the control unit regulates the rotation angles of the first rotating shaft and the second rotating shaft to make the sunlight vertically incident upon the solar panel according to the first angle component and the second angle component of the current incident angle of the sunlight.

7. The image sensor according to claim 6, wherein the multiple photodiodes of the image sensor form at least one pixel sub-array, the multiple micro lenses of the pixels are sensitive to the specific angles whose first angle components change from the maximum negative angle to the maximum positive angle in the same row of the pixel sub-array while keep same in the same column of the pixel sub-array and second angle components change from 0° to 360° in the pixel sub-array.

8. The image sensor according to claim 1, wherein the image sensor is positioned on the supporting plate where unoccupied by the solar panel.
